(19) United States
(12) Patent Application Publication
(10) Pub. No.: US 2025/0368845 A1
(43) Pub. Date: Dec. 4, 2025

(54) LOW-VISCOSITY FLUX COMPOSITION FOR PRINTING USING DIGITAL INKJET HEAD

(71) Applicant: JETBEST CORPORATION, HSINCHU (TW)

(72) Inventors: YI-CHING LU, Hsinchu (TW); IUAN-YUAN WU, Hsinchu (TW); CHIA-HSIANG TZENG, Hsinchu (TW); HSUEH-CHUN WU, Hsinchu (TW); LIH-WEN CHEN, Hsinchu (TW)

(21) Appl. No.: 19/206,103

(22) Filed: May 13, 2025

(30) Foreign Application Priority Data
May 31, 2024 (TW) 113120291

(51) Int. Cl. C09D 11/38; B23K 35/362; C09D 11/033; C09D 11/08; C09D 11/36

(52) U.S. Cl. CPC C09D 11/38; B23K 35/362; C09D 11/033; C09D 11/08; C09D 11/36

(57) ABSTRACT

The present invention provides a low-viscosity flux composition for printing using digital inkjet head, including: a common solvent, which accounts for 63 wt % to 98.5 wt % of the total weight of the flux composition, and includes propylene carbonate and at least one hydroxyl-containing organic solvent, wherein the weight ratio of the propylene carbonate to the hydroxyl-containing organic solvent ranges from 0.02 to 0.83; and an organic acid, which accounts for 1.5 wt % to 20 wt % of the total weight of the flux composition, and includes at least one hydroxyl-containing organic acid. The low-viscosity flux composition has appropriate viscosity itself, and can be directly applied to commercially available inkjet heads for printing, without the need for complicated temperature rising mechanism to reduce the viscosity; also, the printed pattern can remain clear without bleeding, eliminating the need for lowering the temperature after printing to restore the viscosity and reduce the flowability.

### CROSS-REFERENCE TO RELATED APPLICATION

This application claims the priority of Taiwanese patent application No. 113120291, filed on May 31, 2024, which is incorporated herewith by reference.

### BACKGROUND OF THE INVENTION

### 1. Field of the Invention

The present invention relates to a flux composition, and more particularly, to a low-viscosity flux composition for printing using digital inkjet head.

### 2. The Prior Arts

In general soldering, the flux is functioned as chemically removing metal oxides on the surfaces to be bonded between two components to be soldered and spreading over the surfaces to be bonded with good wettability, such that the solder can be tightly bonded and fixed to the interface (such as a metal interface) between the two components to be soldered during subsequent soldering process, thereby obtaining a strongly and firmly bonded assembly.

Digital inkjet printing technology allows jet-printing of ink onto the surface of a target substrate, which not only saves time and materials, but also eliminates the costs and time for screen prefabrication as well as future storage and management of screens compared to conventional screen printing. In addition, it also saves materials compared to spin coating. As a result, a technology for printing flux using digital inkjet printing has been developed.

However, when performing digital inkjet printing with high-viscosity flux, the viscosity of the flux must be reduced before it is stored in the storage tank of the supplying inkjet head. In addition, a heating mechanism is required to be installed on the inkjet head and the piping connecting the inkjet head to the storage tank, to increase the flux temperature and reduce its viscosity, making it easier to be sprayed onto the surface of the substrate. Moreover, a rapid chilling mechanism is also required to be installed on the platform loading the substrate to cool down the flux for preventing it from flowing or shifting. This technical problem has been described, for example, in the patent literature TW 1392423B.

Therefore, in view of the aforementioned issues, the present invention has been developed.

### SUMMARY OF THE INVENTION

In order to solve the above problems, an objective of the present invention is to provide a low-viscosity flux composition for printing using digital inkjet head, which has appropriate viscosity itself, and can be directly applied to commercially available inkjet heads for printing, without the need for complicated temperature rising mechanism to reduce the viscosity; also, the jet-printed (hereinafter referred as to “printed”) pattern can remain clear without bleeding, eliminating the need for lowering the temperature after jet-printing (hereinafter referred as to “printing”) to restore the viscosity and reduce the flowability.

The low-viscosity flux composition provided by the present invention is characterized that by adjusting the ratio between the organic solvent and the hydroxyl-containing resin, a flux composition within appropriate viscosity range can be obtained.

Therefore, in order to achieve the above objectives, the present invention provides a low-viscosity flux composition for printing using digital inkjet head, comprising: a common solvent, which accounts for 63 wt % to 98.5 wt % of a total weight of the flux composition, and includes propylene carbonate and at least one hydroxyl-containing organic solvent, wherein a weight ratio of the propylene carbonate to the hydroxyl-containing organic solvent ranges from 0.02 to 0.83; and an organic acid, which accounts for 1.5 wt % to 20 wt % of the total weight of the flux composition, and includes at least one hydroxyl-containing organic acid.

According to an embodiment, the flux composition further comprises at least one hydroxylamine, which accounts for 10 wt % or less of the total weight of the flux composition, wherein the hydroxylamine comprises at least one of ethanolamine, N,N-dimethylethanolamine, (N,N-dimethylaminoethoxy) ethanol, cyclohexyl diethanolamine, isopropanolamine, diisopropanolamine, and triisopropanolamine.

According to an embodiment, the flux composition further comprises at least one hydroxyl-containing resin, which accounts for 20 wt % or less of the total weight of the flux composition, wherein the hydroxyl-containing resin comprises at least one of a hydrogenated or non-hydrogenated rosin, polyvinyl alcohol, polyvinyl butyral, and an aldehyde ketone resin.

According to an embodiment, the hydroxyl-containing organic acid comprises at least one of glycolic acid, salicylic acid, citric acid, tartaric acid, and malic acid.

According to an embodiment, further, the organic acid may include or not include at least one hydroxyl-free organic acid, wherein the hydroxyl-free organic acid comprises at least one of benzoic acid, levulinic acid, lauric acid, malonic acid, succinic acid, glutaric acid, adipic acid, diglycolic acid, maleic acid, fumaric acid, and dimer fatty acid.

According to an embodiment, the flux composition has a viscosity of 3 mPa·s or greater and 30 mPa·s or less.

According to an embodiment, the flux composition has a surface tension of 25 dyne/cm or greater and 40 dyne/cm or less.

According to an embodiment, the flux composition has a pH value of not greater than 10 and not less than 2.

According to an embodiment, the flux composition has an electrical conductivity of 1 mS/cm or less.

According to an embodiment, the flux composition forms a slightly tacky thin film with a thickness of 0.2 μm or more and 20 μm or less after solvent volatilization.

According to an embodiment, the hydroxyl-containing organic solvent comprises at least one of an alcohol solvent and an alcohol ether solvent.

According to an embodiment, the hydroxyl-containing organic solvent comprises at least one of n-butanol, diacetone alcohol, 1,2-butanediol, 1,5-pentanediol, 1,2-hexanediol, ethylene glycol n-butyl ether, propylene glycol methyl ether, diethylene glycol ethyl ether, and dipropylene glycol methyl ether.

In summary, for the low-viscosity flux composition provided by the present invention, by controlling the ratio between the common solvent (and optionally, a hydroxyl-containing organic acid and hydroxylamine) and the hydroxyl-containing resin, a flux composition within appropriate viscosity range can be obtained. As such, the process of firstly rising the temperature to reduce the viscosity of the flux composition before jetting and then lowering the temperature to restore the viscosity and reduce the flowability is no longer required. For the flux composition provided by the present invention, by using propylene carbonate along with a hydroxyl-containing organic solvent as a comment solvent, the outputted pattern of the flux composition can remain clear without bleeding after printing, while ensuring sufficient wetting and spreading of the solder during soldering. Therefore, the flux composition of the present invention can be directly applied to platform type inkjet printers equipped with commercial inkjet heads, and is compatible with the viscosity specifications of various commercially available inkjet heads.

### DETAILED DESCRIPTION OF THE PREFERRED EMBODIMENT

The following provides a detailed description of the present invention, from which the advantages, features, and embodiments of the present invention will become apparent. However, it should be noted that the present invention is not limited to the following embodiments, and may be implemented in various forms.

In addition, unless expressly stated otherwise, the values mentioned herein are not intended to be exact and may be regarded as approximate, i.e., including errors or ranges expressed by terms such as “about,” “approximately,” or “substantially.” Those skilled in the art will understand that such values may include manufacturing tolerances, measurement errors, and the like, which may fall within ±20%, ±10%, or ±5%.

If without any contradiction, any technical features described in the embodiments of the present specification, including components, contents, and the like, may be applicable to other embodiments of the present invention.

The present invention provides a low-viscosity flux composition for printing using digital inkjet head, which has appropriate viscosity itself, and can be directly applied to various commercially available inkjet heads for printing, without the need for additional heating or cooling devices to change the viscosity; also, the flux composition can remain clear without bleeding after printing.

The flux composition of the present invention comprises: a common solvent, which accounts for 63 wt % to 98.5 wt %, preferably from 63 wt % to 95 wt %, and more preferably from 63 wt % to 89 wt % of a total weight of the flux composition, and includes propylene carbonate and at least one hydroxyl-containing organic solvent, wherein the weight ratio of the propylene carbonate to the hydroxyl-containing organic solvent ranges from 0.02 to 0.9, preferably from 0.08 to 0.85, and more preferably from 0.13 to 0.83; and an organic acid, which accounts for 1.5 wt % to 20 wt %, preferably, accounts for 2 wt % to 15 wt %, more preferably, accounts for 2.5 wt % to 12 wt % of the total weight of the flux composition, and includes at least one hydroxyl-containing organic acid.

In current CoWoS processes, the space between the chip and the micro PCB is limited. Excess flux outside the solder pad areas may cause short circuits after reflow soldering, which severely degrades the yield. Accordingly, the addition of propylene carbonate serves to maintain low flowability of the printed pattern, thereby the flux composition can remain clear without bleeding after printing.

In the present invention, either a single type of hydroxyl-containing organic solvent, or a combination of multiple types of hydroxyl-containing organic solvents may be used.

The addition of the hydroxyl-containing organic solvent serves to reduce the viscosity of the flux composition while assisting the flux composition in adhering closely to the surface of the object to be soldered (e.g., the substrate) after printing, thereby enabling sufficient wetting and spreading of the solder during the subsequent soldering process. Additionally, it can further assist in dissolving the organic acid (especially hydroxyl-containing organic acids) and the hydroxyl-containing resin to be referred later.

The hydroxyl-containing organic solvent may comprise at least one of an alcohol solvent (especially a monohydric alcohol solvent and a dihydric solvent) and an alcohol ether solvent.

The hydroxyl-containing organic solvent may comprise at least one of n-butanol, diacetone alcohol, 1,2-butanediol, 1,5-pentanediol, 1,2-hexanediol, ethylene glycol n-butyl ether, propylene glycol methyl ether, diethylene glycol ethyl ether, and dipropylene glycol methyl ether.

In the present invention, either a single type of organic acid, or a combination of multiple types of organic acids may be used.

The addition of the organic acid serves as a low-viscosity component in the flux composition, which not only provides flux functionality but also helps to appropriately adjust the viscosity of the flux composition. Furthermore, the organic acid can remove metal oxides from the surface of the object to be soldered or from the surface of the solder, thereby lowering the electrical resistance of the surfaces to be bonded.

In the flux composition of the present invention, the organic acid particularly refers to an organic carboxylic acid. The organic acid must comprise at least one hydroxyl-containing organic acid, which may include at least one of glycolic acid, salicylic acid, citric acid, tartaric acid, and malic acid. When multiple types of organic acids are used simultaneously, the organic acid may further comprise an organic acid that does not contain hydroxyl group, i.e., a hydroxyl-free organic acid.

The reason that the organic acid must comprise at least one hydroxyl-containing organic acid is in that such the hydroxyl-containing organic acids have good solubility in the hydroxyl-containing organic solvents, such that it can more easily and closely adhere to the metal surface of the object to be soldered to remove the metal oxides from the surface.

Under the above formulation, the viscosity of the flux composition of the present invention can be adjusted to an appropriate range of 3 mPa·s or greater and 30 mPa·s or less, preferably 4 mPa·s or greater and 20 mPa·s or less, and more preferably 5 mPa·s or greater and 15 mPa·s or less. The flux composition within this low viscosity range is well-suitable for commercially available inkjet heads, as it can be directly stored and used without additional temperature rising or temperature lowering mechanisms.

Furthermore, under the above formulation, the surface tension of the flux composition of the present invention can be adjusted to an appropriate range of 25 dyne/cm or greater and 40 dyne/cm or less, preferably 27.5 dyne/cm or greater and 37.5 dyne/cm or less, and more preferably 30 dyne/cm and 35 dyne/cm or less. The flux composition within this surface tension range can be wet and spread well on the surface to be bonded, while maintaining a clear printed pattern without bleeding.

In addition, under the above formulation, the flux composition of the present invention may have a pH value of not greater than 10 and not less than 2, preferably not greater than 8 and not less than 2.5, and more preferably not greater than 7 and not less than 3.

In addition, under the above formulation, the flux composition of the present invention may have an electrical conductivity of not greater than 1 mS/cm, preferably not greater than 0.95 mS/cm, and more preferably not greater than 0.91 mS/cm.

Moreover, under the above formulation, after printing and complete solvent volatilization, the flux composition of the present invention forms a slightly tacky thin film with a thickness of 0.2 μm or more and 20 μm or less, preferably 0.5 μm or more and 18 μm or less, and more preferably 0.8 μm or more and 15 μm or less.

This slightly tacky thin film is a the residue of the flux composition except for the common solvent, that is: the hydroxyl-containing organic acid; or a mixture of the hydroxyl-containing organic acid and the hydroxyl-free organic acid; or a mixture of the hydroxyl-containing organic acid, the hydroxyl-free organic acid, and the hydroxylamine; or a mixture of the hydroxyl-containing organic acid, the hydroxyl-free organic acid, the hydroxylamine, and the hydroxyl-containing resin. The above slightly tacky thin films with different thicknesses and components can contribute to good soldering and conductive performance after the tin balls are applied and the electronic parts are soldered on micro-circuit boards.

According to an embodiment of the present invention, the organic acid may further comprise at least one hydroxyl-free organic acid, such as at least one of benzoic acid, levulinic acid, lauric acid, malonic acid, succinic acid, glutaric acid, adipic acid, diglycolic acid, maleic acid, fumaric acid, and dimer fatty acid.

According to an embodiment of the present invention, the flux composition may further comprise at least one hydroxylamine, which accounts for no more than 10 wt %, preferably from 1 wt % to 7.5 wt %, and more preferably from 2 wt % to 5 wt % of the total weight of the flux composition.

The hydroxylamine may comprise at least one of ethanolamine, N,N-dimethylethanolamine, (N,N-dimethylaminoethoxy) ethanol, cyclohexyl diethanolamine, isopropanolamine, diisopropanolamine, and triisopropanolamine.

According to an embodiment of the present invention, the flux composition may further comprise at least one hydroxyl-containing resin, which accounts for 20 wt % or less, and preferably 12 wt % or less of the total weight of the flux composition.

The hydroxyl-containing resin particularly refers to a polymer resin. The hydroxyl-containing resin may comprise at least one of a hydrogenated or non-hydrogenated rosin, polyvinyl alcohol, polyvinyl butyral, and an aldehyde ketone resin.

Most of the components used in the flux composition of the present invention contain hydroxyl groups. This is because the presence of hydroxyl groups enhances the mixing effect among the various components, thereby improving the stability of the low-viscosity flux composition. In addition, after the hydroxyl-containing components are mixed with propylene carbonate, all of them can retain the wetting and spreading characteristic of the hydroxyl-containing components, while exhibiting the characteristic of propylene carbonate of allowing the printed patterns to remain clear without bleeding.

Moreover, similar to the organic acids (both the hydroxyl-containing and hydroxyl-free organic acids), the hydroxylamine also serves as a low-viscosity flux component, so that it can also provide flux functionality while appropriately adjusting the viscosity of the flux composition to meet the printing specifications of various commercial inkjet heads, thereby further enhancing the effect of the flux composition of the present invention.

In addition, similar to the organic acids (both the hydroxyl-containing and hydroxyl-free organic acids), the hydroxylamines can also remove the metal oxides from the surface of the object to be soldered or the surface of the solder, thereby reducing the resistance at the surface to be bonded and further enhancing the effect of the flux composition of the present invention.

Additionally, as a high-viscosity component, the use of the hydroxyl-containing resin in combination with other low-viscosity components can adjust the viscosity of the flux composition to an appropriate range.

In the present invention, although the viscosity of the flux composition is reduced for improving the flowability, since the flux composition is mainly applied to digital inkjet printing technology, it is allowed to precisely print the low-viscosity flux onto the bonded surfaces between the objects to be soldered. This effectively prevents excess flux from contaminating surrounding electronic parts, reduces flux waste, and reduces the time required for cleaning large non-soldered areas.

For the low-viscosity flux composition of the present invention, when applied to digital inkjet printing technology, it is not only necessary to precisely print the flux composition onto only the areas to be soldered, but also necessary to maintain the integrity of the pattern formed on the target substrate by the printed ink, in order to avoid excessive bleeding (spreading) during subsequent processes. Accordingly, in the present invention, the addition of propylene carbonate allows the printed pattern to maintain low flowability, thereby remaining clear and precise.

In addition, the hydroxyl-containing organic solvent not only plays a role of reducing the viscosity of the flux composition, but also helps the dissolution of the organic acid.

Furthermore, because the hydroxyl-containing organic solvent can easily guide the flux to adhere to the metal surface of the object to be soldered, it can ensure the printed pattern to retain the characteristics of clear and precise when used with the propylene carbonate. Adjustment of the ratio between these two components can ensure the integrity of the printed pattern without contaminating the surrounding electronic parts, while ensuring the flux to adhere closely to the surface of the object to be soldered, thereby allowing the molten solder to be successfully wet, spread, and fixed between the objects during the subsequent soldering process, and thus provides practicality.

In particular, under the formulation disclosed above, the flux composition of the present invention allows the viscosity of the flux inkjet ink to be adjusted to a low viscosity range of 3 mPa·s to 30 mPa·s, which is suitable for commercially available inkjet heads, and therefore can be stored and used directly.

In practice, since the low-viscosity flux composition for printing using digital inkjet heads of the present invention falls within an appropriate viscosity range itself, it can be directly loaded into ink cartridges or ink packs and then applied directly to the commercial platform type inkjet printer without the need for a process of firstly rising the temperature to reduce the viscosity, followed by printing, and then lowering the temperature to restore the viscosity and reduce the flowability.

Specifically, different inkjet heads have their own suitable specification of viscosities of inks (i.e., the low-viscosity flux composition of the present invention). For example, the suitable ink viscosity for Epson DX5/DX7/13200E/13200U series inkjet head is 3-7 mPa·s; the suitable ink viscosity for Kyocera KJ4A series inkjet head is 6-7.5 mPa·s; the suitable ink viscosity for Kyocera KJ4C series inkjet head is 10-18 mPa·s; the suitable ink viscosity for Xaar 1001 inkjet head is 7-50 mPa·s; the suitable ink viscosity for Ricoh Gen 4 inkjet head is 10-12 mPa·s; the suitable ink viscosity for Trident 256Jet inkjet head is 20-30 mPa·s; the suitable ink viscosity for Konica Minolta KM 512/512i/1024/1024i series inkjet heads is 6-12 mPa·s; and the suitable ink viscosity for Fujifilm® Dimatix StarFire SG1024 inkjet head is 8-20 mPa·s.

Therefore, by adjusting the ratio between the components of the flux composition within the appropriate range disclosed in the present invention, the viscosity of the flux composition can be directly adjusted to match the viscosity specifications of commercially available inkjet heads.

For example, controlling the contents of the common solvent and the hydroxyl-containing resin is the most effective way to obtain flux compositions with viscosities match different commercially available inkjet heads. For example, increasing the amount of the common solvent, reducing the amount of the hydroxyl-containing resin, or even eliminating the addition of the hydroxyl-containing resin can effectively obtain a flux composition with lower viscosity; conversely, increasing the amount of the hydroxyl-containing resin or reducing the amount of the common solvent can effectively obtain a flux composition with higher viscosity.

In addition, waveform adjustments can be made to the electronic board for controlling the printing of the inkjet head, such that the flux composition and the inkjet head voltage can cooperate perfectly, thereby achieving a precise inject printing application.

Moreover, for different models of inkjet heads from the same manufacturer, or even various models of inkjet heads from different manufacturers, as long as the inkjet head design is compatible with the driving board, the droplet size can be appropriately controlled to achieve a precise inject printing application.

### EXAMPLES

### Preparation and Testing of the Flux Composition

The low-viscosity flux compositions of the examples of the present invention and the flux compositions of the comparative examples are prepared by mixing the raw materials under the weight ratios according to the formulation shown in Tables 1 and 2, and stirring until clear liquids are obtained. After filtering the mixed solution of the flux composition, basic physical properties including viscosity, surface tension, pH value, and electrical conductivity were measured. In addition, the printing reliability of the flux compositions applied to a commercially available platform type inkjet printer, the integrity and the degree of bleeding of the printed patterns, and the film thickness after solvent volatilization were also evaluated. These results are recorded in Tables 1 and 2.

The viscosity values shown in Tables 1 and 2 were measured using Brookfield rotational viscometer (model DV-E) at a controlled constant temperature of 25° C. The surface tension values shown in Tables 1 and 2 were measured using a surface surface tension analyzer manufactured by Kyowa Interface Science Co., Ltd. (Japan) (model CBVP-A3) at a controlled constant temperature of 25° C.

The pH values and electrical conductivity values shown in Tables 1 and 2 were measured on individual diluted solutions of respective flux compositions, wherein the dilution ratio was 1 part by weight of the flux composition to 39 parts by weight of deionized water, and the diluted solution was stirred at room temperature for one hour before measurement. The pH value is measured using a pH meter (model PH 200) from Clean Instruments; the electrical conductivity value is measured using an electrical conductivity meter (model Cond 3310) from WTW company.

Inkjet printing tests of the flux compositions, including evaluation of the printing reliability, the integrity and the degree of bleeding of the printed patterns, are conducted using Roland VS-300 and Mimaki UJF-3042 platform type inkjet printers. The tests were respectively performed on flux compositions with viscosities of approximately 4˜7 mPa·s and 8˜20 mPa·s, respectively. During the tests, control of jetting volume was available, and both single-pass and multi-pass printing can be employed.

The film thickness (μm) shown in Tables 1 and 2 were measured using a non-contact film thickness meter on respective slightly tacky thin films. These thin films are obtained by printing each flux composition onto a circuit board using Roland VS-300 and Mimaki UJF-3042 platform type inkjet printers, and heating the circuit board along with the printed material to remove the organic solvent. The non-contact film thickness meter is CLPT010 manufactured by Keyence Corporation.

### Evaluation Criteria for the Printing Reliability of the Flux Compositions Applied to the Inkjet Printer

⊚: After printing the flux composition using the inkjet printer, no ink misting occurred, and no missing line is found in the test strip pattern of the nozzle check.
∘: After printing of the flux composition using the inkjet printer, slight ink misting occurred, or the number of missing lines found in the test strip pattern of the nozzle check ≤2.
x: After printing of the flux composition using the inkjet printer, fail to print, or severe ink misting occurred, or the number of missing lines found in the test strip pattern of the nozzle check ≥3.
   Standby Evaluation Criteria for the Flux Composition in the Inkjet Printers (Excluding Examples with Printing Reliability Evaluation Results of “x”)
⊚: After leaving the flux composition on standby in the inkjet printer overnight without cleaning the printer's interior, no missing line is found in the test strip pattern of the nozzle check.
∘: After leaving the flux composition on standby in the inkjet printer overnight without cleaning the printer's interior, missing line(s) is (are) found in the test strip pattern of the nozzle check; but after further cleaning the printer's interior for ≤2 times, no more missing line is found.
x: After leaving the flux composition on standby in the inkjet printer overnight without cleaning the printer's interior, missing line(s) is (are) found in the test strip pattern of the nozzle check; and even after further cleaning the printer's interior for >2 times, the problem of missing line is still present.
   Evaluation Criteria for the Printed Samples after Printing

After printing, the solvent was dried, and the printed pattern was observed using an optical microscope. The film thickness of a single-pass printed pattern was recorded.
⊚: The pattern is clear without bleeding.
∘: The pattern is clear, or slight bleeding occurred.
x: The pattern is unclear, or severe bleeding occurred.

TABLE 1
Composition ratios and test results of each flux composition in Examples 1 to 12.

| | | Flux composition | | | | | | | | | | | |
|---|---|---|---|---|---|---|---|---|---|---|---|---|---|
| | | 1 | 2 | 3 | 4 | 5 | 6 | 7 | 8 | 9 | 10 | 11 | 12 |
| Propylene carbonate | | 2 | 2 | 2 | 40 | 10 | 10 | 10 | 20 | 20 | 20 | 20 | 10 |
| Hydroxyl- | Diacetone | 96.5 | 95.5 | 93.5 | 48 | 68 | 43 | 58 | 48 | 59 | 57 | 44 | 56 |
| containing | alcohol | | | | | | | | | | | | |
| organic | 1,2-hexane | — | — | — | — | 10 | 10 | 5 | 10 | 10 | 10 | 10 | 10 |
| solvent | diol | | | | | | | | | | | | |
| | Dipropylene | — | — | — | — | — | — | 5 | — | — | — | 5 | — |
| | glycol methyl | | | | | | | | | | | | |
| | ether | | | | | | | | | | | | |
| Hydroxyl- | Citric acid | 0.5 | 0.5 | 0.5 | 2 | 2 | 2 | 2 | — | 1 | — | 1 | 2 |
| containing | Glycolic acid | — | — | — | — | — | — | — | 2 | 2 | 1 | 2 | — |
| organic | | | | | | | | | | | | | |
| acid | | | | | | | | | | | | | |
| Hydroxyl- | Levulinic acid | | 2 | 2 | 5 | 5 | 10 | 5 | 18 | 5 | 2 | 5 | 5 |
| free | Diglycolic acid | 1 | — | — | — | — | — | — | — | — | — | — | — |
| organic | | | | | | | | | | | | | |
| acid | | | | | | | | | | | | | |
| Hydroxyl | N,N-Dimethyl | | | 2 | 5 | 5 | 5 | 5 | 2 | 2 | 10 | 2 | 5 |
| amine | ethanolamine | | | | | | | | | | | | |
| | Cyclohexyl | — | — | — | — | — | — | — | — | 1 | — | 1 | — |
| | diethanolamine | | | | | | | | | | | | |
| Hydroxyl- | Rosin | — | — | — | — | — | 20 | 10 | — | — | — | 10 | 10 |
| containing | Aldehyde | — | — | — | — | — | — | — | — | — | — | — | 2 |
| resin | ketone resin | | | | | | | | | | | | |
| Physical | Viscosity | 4.46 | 4.01 | 4.11 | 4.9 | 7.01 | 19.1 | 10.8 | 7.01 | 5.95 | 5.18 | 10.1 | 14.7 |
| properties | (mPa · s) | | | | | | | | | | | | |
| | Surface tension | 31.8 | 31.6 | 32.1 | 35.8 | 33.2 | 34.3 | 33.7 | 34.8 | 33.6 | 33.2 | 34.3 | 34.1 |
| | (dyne/cm) | | | | | | | | | | | | |
| | pH | 2.25 | 2.64 | 5.66 | 5.09 | 5.15 | 4.13 | 4.81 | 3.2 | 3.81 | 10.0 | 3.78 | 4.85 |
| | Electrical | 0.45 | 0.32 | 0.44 | 0.91 | 0.85 | 0.8 | 0.82 | 0.44 | 0.56 | 0.57 | 0.52 | 0.8 |
| | Conductivity | | | | | | | | | | | | |
| | (mS/cm) | | | | | | | | | | | | |

| | | | | | | | | | | | | |
|---|---|---|---|---|---|---|---|---|---|---|---|---|
| Printing reliability | ⊚ | ◯ | ⊚ | ⊚ | ⊚ | ⊚ | ⊚ | ⊚ | ⊚ | ◯ | ⊚ | ◯ |
| evaluation | | | | | | | | | | | | |
| Standby evaluation | ◯ | ◯ | ◯ | ⊚ | ⊚ | ⊚ | ⊚ | ◯ | ⊚ | ◯ | ⊚ | ◯ |
| Printed sample evaluation | ◯ | ◯ | ⊚ | ⊚ | ⊚ | ⊚ | ⊚ | ⊚ | ⊚ | ◯ | ⊚ | ⊚ |
| Average thickness of printed | 0.3 | 0.53 | 0.78 | 0.98 | 1.2 | 18.5 | 11.4 | 7.8 | 3.5 | 1.6 | 13.8 | 15.1 |
| sample after solvent | | | | | | | | | | | | |
| volatilization (μm) | | | | | | | | | | | | |

TABLE 2
Composition ratios and test results of each flux
composition in Comparative Examples C1 to C4.

| Flux composition | | C1 | C2 | C3 | C4 |
|---|---|---|---|---|---|
| propylene carbonate | | — | — | 10 | 20 |
| Hydroxyl-containing | Diacetone alcohol | 90 | 89 | 68 | 40 |
| organic solvent | 1,2-hexanediol | — | — | — | — |
| | Dipropylene glycol | — | — | — | — |
| | methyl ether | | | | |
| Hydroxyl-containing | Citric acid | — | 1 | — | 0.5 |
| organic acid | Glycolic acid | — | — | 22 | — |
| Hydroxyl-free | Levulinic acid | 5 | 5 | — | 20 |
| organic acid | Diglycolic acid | — | — | — | — |
| Hydroxylamine | N,N- | 5 | 5 | — | 10 |
| | Dimethylethanolamine | | | | |
| | Cyclohexyl | — | — | — | |
| | diethanolamine | | | | |
| Hydroxyl-containing | Rosin | — | — | — | 9.5 |
| resin | Aldehyde ketone resin | — | — | — | — |
| Physical properties | Viscosity (mPa · s) | 4.71 | 5.15 | 7.39 | 15.9 |
| | Surface | 32.6 | 32.5 | 35.1 | 36.6 |
| | tension (dyne/cm) | | | | |
| | pH | 8.94 | 6.6 | 1.81 | 4.38 |
| | Electrical | 0.66 | 0.85 | 1.17 | 1.57 |
| | Conductivity (mS/cm) | | | | |

| | | | | |
|---|---|---|---|---|
| Printing reliability evaluation | ◯ | ◯ | X | X |
| Standby evaluation | X | ◯ | — | — |
| Printed sample evaluation | X | X | — | — |
| Average thickness of printed sample | 0.18 | 0.23 | — | — |
| after solvent volatilization (μm) | | | | |

Note: The viscosity, surface tension, pH, and electrical conductivity values of the flux compositions shown in Tables 1 and 2 were all measured at a constant temperature of 25° C. Examples 1˜5 and 8˜10 in Table 1 and Comparative Examples C1˜C3 in Table 2 were printed using a modified Roland VS-300 platform type inkjet printer, while Examples 6˜7 and 11˜12 in Table 1 and Comparative Example C4 in Table 2 were printed using a Mimaki UJF-3042 platform type inkjet printer. The printing reliability evaluation, the standby evaluation, and the printed sample evaluation were conducted, respectively. The thickness value of the printed sample represents the average thickness of the one-pass or multi-pass printed flux composition after volatilization of the comment solvent.

The flux compositions of Examples 1 to 12 in Table 1 were printed onto micro-circuit boards using platform type inkjet printer Roland VS-300 or Mimaki UJF-3042, then the micro-circuit boards were applied with solder balls and soldered with electronic parts, and good soldering and electric conduction performance were achieved among all of them.

Due to the absence of propylene carbonate, Comparative Examples C1 to C2 in Table 2 showed severe bleeding and unclear patterns in the printed samples. In contrast, due to the addition of propylene carbonate, Examples 1 to 12 showed clear or sharp printed patterns.

The results of Examples 2 and 4 showed that when the weight ratio of propylene carbonate to all hydroxyl-containing organic solvents ranges from 0.02 to 0.83, good (∘) to excellent (⊚) results of printing reliability evaluation, standby evaluation and printed sample evaluation can be achieved; and when the weight ratio of propylene carbonate to all hydroxyl-containing organic solvents is increased to 0.13, as in Example 5, excellent (⊚) results of printing reliability evaluation, standby evaluation and printed sample evaluation can be obtained.

The results of Examples 6 and 1 showed that when the total amount of the common solvent accounts for 63 wt % to 98.5 wt % of the flux composition, good (∘) to excellent (⊚) results of printing reliability evaluation, standby evaluation and printed sample evaluation can be obtained. The results of Example 9 showed that when the total amount of the common solvent accounts for 89 wt % of the flux composition, excellent (⊚) results of printing reliability evaluation, standby evaluation and printed sample evaluation can be obtained.

The results of Examples 1 and 8 showed that when all organic acids accounts for 1.5 wt % to 20 wt % of the total weight of the flux composition, good (∘) to excellent (⊚) results of printing reliability evaluation, standby evaluation and printed sample evaluation can be obtained.

The results of Comparative Examples C3˜C4 showed that when the amount of the organic acids exceeds 20 wt % of the total weight of the flux composition, it leads to excessively high electrical conductivity or too low pH values, and the actual on-machine data exhibited defects that such compositions are not suitable for standby, and even unsuitable for digital inkjet printing, etc.

The results of Examples 1 to 2 and 10 showed that when no hydroxylamine is added or the amount of hydroxylamine does not exceed 10 wt % of the total weight of the flux composition, the flux compositions achieve good inkjet printing reliability and printed sample evaluation; and when the amount of hydroxylamine added accounts for 2 wt % to 5 wt % of the total weight of the flux composition, the flux compositions achieve excellent inkjet printing reliability and standby evaluation, as well as good printed sample evaluation.

The compared results between Examples 1 to 5 and Examples 6 and 12 showed that the addition of hydroxyl-containing resin can effectively increase the viscosity of the flux compositions, making them suitable for inkjet heads with specification of higher viscosity of inks; furthermore, as the amount of hydroxyl-containing resin increases, the viscosity of the flux composition can be adjusted to higher values.

What is claimed is:

1. A low-viscosity flux composition for printing using digital inkjet head, comprising:
a common solvent, which accounts for 63 wt % to 98.5 wt % of a total weight of the flux composition, and includes propylene carbonate and at least one hydroxyl-containing organic solvent, wherein a weight ratio of the propylene carbonate to the hydroxyl-containing organic solvent ranges from 0.02 to 0.83; and
an organic acid, which accounts for 1.5 wt % to 20 wt % of the total weight of the flux composition, and includes at least one hydroxyl-containing organic acid.

2. The flux composition according to claim 1, further comprising at least one hydroxylamine, which accounts for 10 wt % or less of the total weight of the flux composition.

3. The flux composition according to claim 2, wherein the hydroxylamine comprises at least one of ethanolamine, N,N-dimethylethanolamine, (N,N-dimethylaminoethoxy) ethanol, cyclohexyl diethanolamine, isopropanolamine, diisopropanolamine, and triisopropanolamine.

4. The flux composition according to claim 1, further comprising at least one hydroxyl-containing resin, which accounts for 20 wt % or less of the total weight of the flux composition.

5. The flux composition according to claim 4, wherein the hydroxyl-containing resin comprises at least one of a hydrogenated or non-hydrogenated rosin, polyvinyl alcohol, polyvinyl butyral, and an aldehyde ketone resin.

6. The flux composition according to claim 1, wherein the hydroxyl-containing organic acid comprises at least one of glycolic acid, salicylic acid, citric acid, tartaric acid, and malic acid.

7. The flux composition according to claim 1, wherein the organic acid further includes at least one hydroxyl-free organic acid, wherein the hydroxyl-free organic acid comprises at least one of benzoic acid, levulinic acid, lauric acid, malonic acid, succinic acid, glutaric acid, adipic acid, diglycolic acid, maleic acid, fumaric acid, and dimer fatty acid.

8. The flux composition according to claim 1, wherein the flux composition has a viscosity of 3 mPa·s or greater and 30 mPa·s or less.

9. The flux composition according to claim 1, wherein the flux composition has a surface tension of 25 dyne/cm or greater and 40 dyne/cm or less.

10. The flux composition according to claim 1, wherein the flux composition has a pH value of not greater than 10 and not less than 2.

11. The flux composition according to claim 1, wherein the flux composition has an electrical conductivity of 1 mS/cm or less.

12. The flux composition according to claim 1, wherein the flux composition forms a slightly tacky thin film with a thickness of 0.2 μm or more and 20 μm or less after solvent volatilization.

13. The flux composition according to claim 1, wherein the hydroxyl-containing organic solvent comprises at least one of an alcohol solvent and an alcohol ether solvent.

14. The flux composition according to claim 1, wherein the hydroxyl-containing organic solvent comprises at least one of n-butanol, diacetone alcohol, 1,2-butanediol, 1,5-pentanediol, 1,2-hexanediol, ethylene glycol n-butyl ether, propylene glycol methyl ether, diethylene glycol ethyl ether, and dipropylene glycol methyl ether.
